(19) United States
(12) Patent Application Publication
(10) Pub. No.: US 2023/0209876 A1
(43) Pub. Date: Jun. 29, 2023

(54) FLAT PANEL DISPLAY HAVING META LENS AND PERSONAL IMMERSION DISPLAY INCLUDING THE SAME

(71) Applicant: LG Display Co., Ltd., Seoul (KR)

(72) Inventor: SeungJu YOON, Paju-si (KR)

(73) Assignee: LG Display Co., Ltd., Seoul (KR)

(21) Appl. No.: 17/943,860

(22) Filed: Sep. 13, 2022

(30) Foreign Application Priority Data
Dec. 29, 2021 (KR) 10-2021-0191108

(51) Int. Cl. H01L 51/52

(52) U.S. Cl. CPC H01L 51/5275; H01L 27/3211

(57) ABSTRACT

A flat panel display having a meta-lens and a personal immersion display including the same are discussed. The flat panel display can include a display panel including a display area having a first surface area, a first meta-lens disposed on the display panel to correspond to the display area, a transparent layer disposed on the first meta-lens and having a first thickness, a viewing area having a second surface area smaller than the first surface area and defined on an upper surface of the transparent layer, and a second meta-lens disposed on the upper surface of the transparent layer to correspond to the viewing area.

### CROSS-REFERENCE TO RELATED APPLICATIONS

This application claims priority to Korean Patent Application No. 10-2021-0191108 filed in the Republic of Korea on Dec. 29, 2021, the entire contents of which are hereby expressly incorporated by reference into the present application.

### BACKGROUND

### Field of the Invention

The present disclosure relates to a flat panel display having a meta-lens and a personal immersion display including the same. In particular, the present disclosure relates to a flat panel display in which the physical resolution is optically improved using a meta-lens, and a personal immersion display including the same.

### Discussion of the Related Art

As the information society develops, the demands for display apparatus are also increasing in various manners. For example, various flat panel display apparatuses such as a liquid crystal display (or LCD), a plasma display panel (or PDP), an organic light emitting display (or OLED), and a micro LED display have been developed.

Among the display apparatus, the electroluminescence display is a self-luminous display, which has superior optical performances such as a viewing angle and contrast ratio compared to the liquid crystal display. The electroluminescence display does not require a backlight unit, so it has the advantage of lightweight and thin structure and low power consumption. With these advantages, it is attracting attention as the most suitable display device for implementing 8K ultra high resolution displays beyond 4K resolution.

Recently, a personal immersion device using an electroluminescence display having an organic light emitting element that is easy to realize super high resolution has been developed. The personal immersion device includes a personal immersion display or a head mounted display (HMD) that can be mounted in close contact with a user's eyes. The personal immersion display is a spectacle type monitor device for virtual reality (VR) or augmented reality (AR) that is worn in the form of glasses or a helmet to provide video images at a distance close to the user's eyes.

Since the personal immersion display is worn on the body by an individual, it is preferable that the weight can be reduced as much as possible. Until now, the personal immersion display uses lenses because the distance from the eyes is very close and the image needs to be provided according to the focus of the user's eyes. In addition, since the lens has a curved surface, the optical problems such as curved aberration and chromatic aberration may occur, so a convex lens and a concave lens are used in combination. Therefore, there can be a limitation in that the personal immersion display can have a heavy weight due to the lens system.

The structure of the personal immersion display can be complicated because it is configured by combining the display panel and the lens system. Accordingly, there is a demand for the development of a new personal immersion display having an ultra-thin and ultra-light weight structure by excluding the conventional lens system, which may address optical problems such as chromatic aberration or curved aberration.

In addition, there is a limit to increasing the resolution in the personal immersion display. Since flat panel displays applied to TVs and monitors have a large screen area, there is still room for designing higher resolution. However, since the screen area of the personal immersion display can be very small, there can be a limit to further increasing the resolution. Accordingly, there is a demand for a new flat panel display capable of further increasing the optical resolution while implementing the maximum physical resolution.

### SUMMARY OF THE DISCLOSURE

Accordingly, the present disclosure, as for solving or addressing the problems and limitations described above, is to provide a flat panel display with further optically improved resolution, in implementing the ultra-high resolution.

The present disclosure is also to provide a personal immersion display having an ultra-lightweight and ultra-high-resolution structure by eliminating a conventional lens system including a convex lens and concave lens.

In an aspect of the present disclosure, a flat panel display can comprise a display panel including a display area having a first surface area, a first meta-lens disposed on the display panel to correspond to the display area, a transparent layer disposed on the first meta-lens and having a first thickness, a viewing area having a second surface area smaller than the first surface area and defined on an upper surface of the transparent layer, and a second meta-lens disposed on the upper surface of the transparent layer to correspond to the viewing area.

In one aspect, the first meta-lens converts incident light from the display area to emit output light directed to the viewing area. The second meta-lens converts the output light provided in the viewing area into parallel light and emits the parallel light directed to outside.

In one aspect, the output light is formed by focusing and deflecting the incident light corresponding to the first surface area to the second surface area. The parallel light is formed by maintaining the output light corresponding to the second surface area in parallel with same area.

In one aspect, the display panel includes a plurality of pixels arrayed in the display area with a N×M matrix manner, where N and M are natural numbers. A plurality of pixel viewing areas are arrayed in the viewing area with the N×M matrix manner corresponding to the pixels.

In one aspect, each pixel has a pixel size. The first meta-lens includes a plurality of first unit meta-lenses allocated to each pixel. Each pixel viewing area has a pixel viewing size smaller than the pixel size. The second meta-lens includes a plurality of second unit meta-lenses allocated to each pixel viewing area.

In one aspect, each of the first unit meta-lenses corresponds one-to-one with each of the second unit meta-lenses, respectively. The first unit meta-lens provides incident light from the pixel corresponding to the first unit meta-lens to the pixel viewing area allocated to the second unit meta-lens corresponding to the first unit meta-lens. The second meta-lens converts the incident light to emit as the parallel light.

In one aspect, each pixel includes at least three sub-pixels. Each of the pixel viewing areas includes at least three sub viewing areas corresponding to the at least three sub-pixels.

In one aspect, each of the sub-pixels has a sub pixel size. The first unit meta-lens includes a first sub meta-lens allocated to each of the sub-pixels. Each of the sub viewing areas includes a sub viewing size smaller than the sub pixel size. The second unit meta-lens includes a second sub meta-lens allocated to each of the sub viewing areas.

In one aspect, the first sub meta-lenses correspond to one-to-one with each of the second sub meta-lenses. The first sub meta-lens provides incident light from the sub-pixel corresponding to the first sub meta-lens to the sub viewing area allocated to the second sub meta-lens corresponding to the first sub meta-lens. The second sub meta-lens converts the incident light to emit as the parallel light.

In one aspect, the transparent layer has a refractive index smaller than the first meta-lens and the second meta-lens.

In one aspect, the display panel includes a driving element layer disposed on the substrate, a planarization layer covering the driving element layer, a light emitting element layer disposed on the planarization layer, and a color filter layer disposed on the light emitting element layer.

In one aspect, the light emitting element layer includes a first electrode disposed in each of the plurality of pixels arrayed in the N×M matrix manner on the planarization layer, an emission layer on the first electrode, and a second electrode on the emission layer as covering the plurality of pixels.

In one aspect, the color filter layer includes a plurality of color filters allocated to each of the plurality of pixels.

A flat panel display according to an embodiment of the present disclosure can include a display panel and a meta-lens formed on the upper surface of the display panel. The meta-lens can provide a user with a pixel of which size is optically reduced from the physical size of the pixel formed on the display panel. As a result, the flat panel display according to the present disclosure can provide higher optical resolution than the physical resolution.

In addition, the flat panel display according to the present disclosure can directly transmit image information to the image area that is optically focused on the user's eyes, so that a personal immersion display can be realized without a lens system. Accordingly, the present disclosure can provide a personal immersion display having a simple component and an ultra-lightweight and ultra-thin structure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a perspective view illustrating a schematic structure of a flat panel display according to the present disclosure;

FIG. 2 is a cross-sectional view along cutting line I-I′ in FIG. 1, for illustrating a structure of a flat panel display according to a first aspect of the present disclosure;

FIG. 3 is a cross-sectional view along cutting line I-I′ in FIG. 1, for illustrating a structure of a flat panel display according to a second aspect of the present disclosure;

FIG. 4 is a perspective view illustrating the structure of one pixel in a flat panel display according to a third aspect of the present disclosure;

FIG. 5 is an enlarged view illustrating one example of meta-lens for a flat panel display according to the present disclosure;

FIG. 6 is a plan view illustrating a structure of a display panel included in a flat panel display according to the present disclosure;

FIG. 7 is an enlarged plan view illustrating a structure of a display panel included in a flat panel display according to the present disclosure;

FIG. 8 is an enlarged cross-sectional view along cutting line II-IF in FIG. 7, for illustrating a structure of a display panel included in a flat panel display according to the present disclosure;

FIG. 9 is a diagram illustrating an example of a personal immersion display according an aspect of the present disclosure; and

FIG. 10 is a diagram illustrating a state of wearing a personal immersion display according to an aspect of the present disclosure.

### DETAILED DESCRIPTION OF THE EMBODIMENTS

Reference will now be made in detail to the exemplary aspects of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these example aspects are provided so that this disclosure can be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example aspects of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration can unnecessarily obscure an important point of the present disclosure, a detailed description of such known function or configuration may be omitted or may be provided briefly.

In the present specification, where the terms “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various aspects of the present disclosure, where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed therebetween. Further, if a first element is described as positioned “on” a second element, it does not necessarily mean that the first element is positioned above the second element in the figure. The upper part and the lower part of an object concerned can be changed depending on the orientation of the object. Consequently, where a first element is described as positioned “on” a second element, the first element can be positioned “below” the second element or “under” the second element in the figure or in an actual configuration, depending on the orientation of the object.

In describing a temporal relationship, when the temporal order is described as, for example, “after,” “subsequent,” “next,” or “before,” a case which is not continuous can be included unless a more limiting term, such as “just,” “immediate(ly),” or “direct(ly),” is used.

It will be understood that, although the terms “first,” “second,” and the like can be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) can be used. These terms are used merely to distinguish one element from another, and not to define a particular nature, order, sequence, or number of the elements. Where an element is described as being “linked”, “coupled,” or “connected” to another element, that element can be directly or indirectly connected to that other element unless otherwise specified. It is to be understood that additional element or elements can be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in a co-dependent relationship.

Hereinafter, examples of a flat panel display according to the present disclosure will be described in detail with reference to the attached drawings. All the components of each flat panel display according to all embodiment of the present disclosure are operatively coupled and configured. Further, wherever possible, the same reference numbers will be used throughout the drawings to refer to the same or like parts. Since a scale of each of elements shown in the accompanying drawings can be different from an actual scale for convenience of description, the present disclosure is not limited to the scale shown in the drawings.

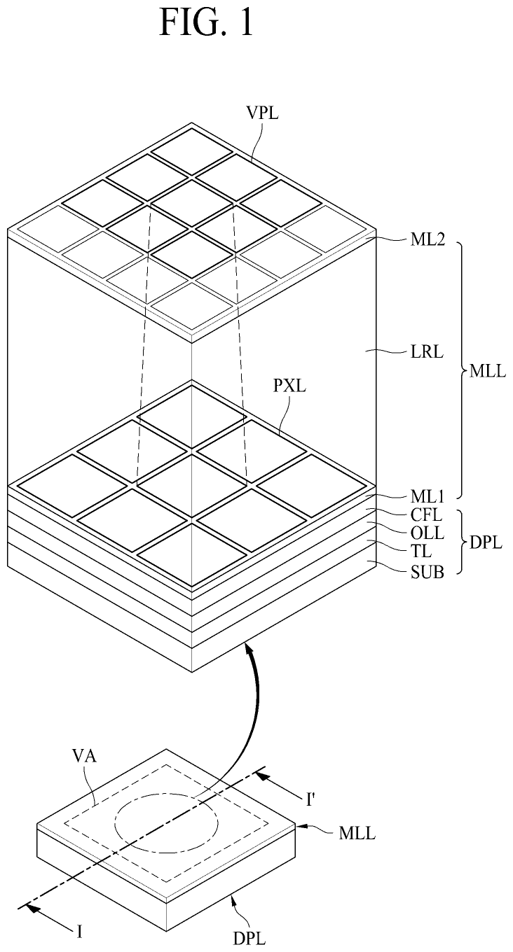

Hereinafter, referring to FIG. 1, a flat panel display according to the present disclosure will be explained. FIG. 1 is a perspective view illustrating a schematic structure of a flat panel display according to the present disclosure. A flat panel display according to the present disclosure comprises a display panel DPL. The display panel DPL, as a flat display panel, can be any one of an electroluminescence display panel, a micro display panel and a liquid crystal display panel. On the upper surface of the display panel DPL, a meta-lens layer MLL is disposed. A viewing area VA is defined on the upper surface of the meta-lens layer MLL. The viewing area VA has an area smaller than the display area defined in the display panel.

For example, the display panel DPL includes a substrate SUB, a driving element layer TL, a light emitting element layer OLL and a color filter layer CFL. The meta-lens layer MLL can include a first meta-lens ML1, a transparent layer LRL and a second meta-lens ML2. The display panel DPL can include a plurality of pixels PXL in a matrix manner. In addition, a plurality of pixel viewing area VPL can be disposed on the upper surface of metal-lens layer MLL. Each of the plurality of pixels PXL disposed on the display panel DPL and each of the pixel viewing area VPL disposed on the metal-lens layer MLL can be arranged to correspond one-to-one.

For example, a plurality of pixels PXL can be arranged in an N×M matrix at the display area PA. Similarly, at the viewing area VA, a plurality of pixel viewing areas VPL can be arranged in an N×M matrix manner. Here, N and M are natural number. The plurality of pixels PXL can match to the plurality of pixel viewing areas VPL as a one-to-one correspondence.

The substrate SUB can be made of glass, plastic, metal or silicon wafer. When the display panel is top emission type, the substrate SUB can be opaque. A driving element layer TL can be formed on the substrate SUB. A light emitting element layer OLL can be formed on the driving element layer TL. The light emitting element layer OLL can include a plurality of pixels PXL. Each of pixels PXL can include a light emitting element providing image information. The driving element layer TL can include thin film transistors for driving the light emitting element disposed in the light emitting element layer OLL. The detailed description thereof will be explained by giving an example of the display panel in the later of the present disclosure.

A color filter layer CFL can be formed on the light emitting element layer OLL. The color filter layer CFL can include color filters representing red, green and blue colors disposed in a matrix manner. For example, the color filters of the color filter layer CFL can match to the pixels PXL as one-to-one correspondence.

A first meta-lens layer ML1 is formed on the color filter layer CFL. The first metal-lens ML1 is an ultra-thin film formed using a metal material, and can have a lens function. For example, the first meta-lens ML1 can have a function of adjusting an optical path, in which lights provided by the pixels PXL having the first area are condensed and/or deflected to the pixel viewing area VPL having the second area at a focal length separated by a predetermined distance from the pixel PXL. A detailed description for the meta-lens will be explained later.

A transparent layer LRL is disposed on the first meta-lens ML1. The transparent layer LRL can be an optical medium layer for guiding the light of which path has been adjusted by the first meta-lens ML1 to travel in the adjusted direction. For example, when the first meta-lens ML1 has a function of condensing lens with a focal length, it is preferable that the transparent layer LRL can have a thickness corresponding to the focal length. In addition, it if preferable that the first meta-lens ML1 can have a higher refractive index than air, and the transparent layer LRL can have a lower refractive index than that of the first meta-lens ML1. Accordingly, any light-loss may not occur in the transparent layer LRL having a relatively low refractive index with respect to light incident from the first meta-lens ML1 having a relatively high refractive index.

A second meta-lens ML2 is disposed on the transparent layer LRL. The second meta-lens ML2 can have a function of converting the light provided by the first meta-lens ML1 into parallel light and adjusting the light path to provide the parallel light to the outside of the display panel DPL.

As a result, the light emitted from the pixel PXL having the first area is irradiated to the pixel viewing area VPL having the second area by the first meta-lens ML1, and is converted into parallel light by the second meta-lens ML2, finally the pixel information having the second area can be provided. Here, it is preferable that the second area of the pixel viewing area VPL can be smaller than the first area of the pixel PXL. For example, when the resolution of the pixels PXL disposed on the display panel DPL is 300 DPI (dots per inch), the resolution in the viewing area VA can be increased to 400 DPI or more due to the meta-lens layer MLL.

<First Aspect>

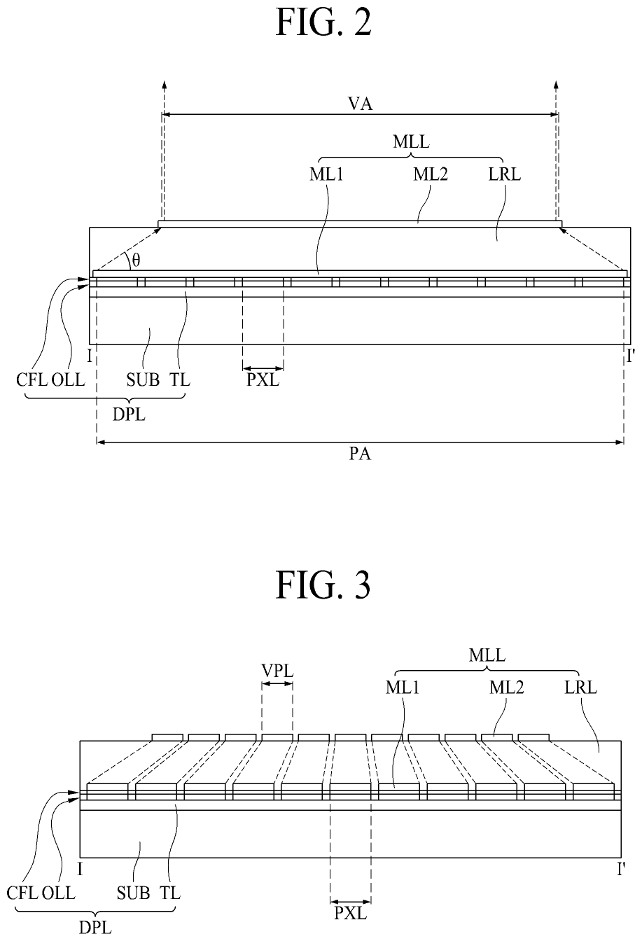

Hereinafter, referring to FIG. 2, the first aspect of the present disclosure will be described. FIG. 2 is a cross-sectional view along cutting line I-I′ in FIG. 1, for illustrating a structure of a flat panel display according to a first aspect of the present disclosure.

A flat panel display according to the first aspect of the present disclosure comprises a display panel DPL and a meta-lens layer MLL formed on the upper surface of the display panel DPL. The display panel DPL can include a substrate SUB, a driving element layer TL, a light emitting element layer OLL and a color filter layer CFL. The meta-lens layer MLL can include a first meta-lens ML1, a transparent layer LRL and a second meta-lens ML2.

The display area PA can be defined at the display panel DPL. The display area PA can have a first surface area. A plurality of pixels PXL can be disposed on the display area PA. Each pixel PXL can have one light emitting element and one color filter. The first meta-lens ML1 can be disposed on the color filter layer CFL.

The first meta-lens ML1 can have slightly larger area than the display area PA, and covers all of the display area PA. The transparent layer LRL can be disposed on the first meta-lens ML1. A viewing area VA can be defined at the upper surface of the transparent layer LRL. The viewing area VA can overlap the display area PA, and have a second surface area. The second surface area can be smaller than the first surface area of the display area PA.

The second meta-lens ML2 can be disposed on the transparent layer LRL. The second meta-lens ML2 can have slightly larger area than the viewing area VA, and cover all of the viewing area VA. The second meta-lens ML2 can convert light incident from the upper surface of the transparent layer LRL into the parallel light that travels in parallel without being diffused or condensed, and then emitted the parallel light to the outside.

The first meta-lens ML1 has a beam-steering function by which the light emitted from the display area PA can be condensed to a range of the viewing area VA at the upper surface of the transparent layer LRL apart from the display panel DPL with a focal length corresponding to the thickness of the transparent layer LRL. In addition, the second meta-lens ML2 can have a beam-steering function by which the light condensed into the viewing area VA is no longer condensed, but travels in parallel straight. Finally, according to the flat panel display of the first aspect, the final image information of the display area PA can be provided in an area corresponding to the viewing area VA.

In the first aspect, all of the plurality of pixels PXL disposed in a matrix manner within the first surface area of the display area PA can be rearranged in a matrix manner within the second surface area of the viewing area VA. Therefore, there is an effect in which the size of the pixel PXL can be reduced and the resolution can be increased.

For example, the first meta-lens ML1 can be formed so that the angle θ of the straight line connecting the outermost of the display area PA to the outmost of the viewing area VA with respect to the surface of the display area PA can be 15 degree, and the transparent layer LRL can have the thickness of 2 μm (micro-meter). In that case, the viewing area VA can have an area of 75% of that of the display area PA. This leads to a result that the resolution of the images of the pixel PL disposed in the viewing area VA is 25% higher than that of the pixel PXL disposed in the display area PA.

As applying the flat panel display according to the first aspect of the present disclosure to a personal immersion display, the image information of the display panel can be provided in a viewing area corresponding to the user's eye focus without using conventional lens system. Since the conventional heavy and bulky convex and/or concave lenses are not used, the volume and weight can be remarkably reduced. In addition, a very simple structure can be provided by stacking ultra-thin meta-lens layers on the display panel without using any conventional lens system.

<Second Aspect>

Hereinafter, referring to FIG. 3, the second aspect of the present disclosure will be explained. FIG. 3 is a cross-sectional view along cutting line I-I′ in FIG. 1, for illustrating a structure of a flat panel display according to a second aspect of the present disclosure.

A flat panel display according to the second aspect of the present disclosure comprises a display panel DPL and a meta-lens layer MLL formed on the upper surface of the display panel DPL. The display panel DPL can include a substrate SUB, a driving element layer TL, a light emitting element layer OLL and a color filter layer CFL. The meta-lens layer MLL can include a first meta-lens ML1, a transparent layer LRL and a second meta-lens ML2. As explained above, the basic structure of the flat panel display according to the second aspect is substantially the same as that of the flat panel display according to the first aspect. The difference is that, in the second aspect, the first meta-lens ML1 has a size corresponding to each pixel PXL, and is disposed separately for each pixel PXL. Further, the second meta-lens ML2 is disposed separately for each pixel viewing area VPL, and has a size corresponding to the pixel viewing area VPL which is an image of the pixels PXL that have been resized by the first meta-lens ML1 and re-arranged on the upper surface of the transparent layer LRL.

Hereinafter, the description for the second aspect will be explained focusing on the main features of the second aspect. A plurality of pixels PXL are disposed in a matrix manner at the display panel DPL. A plurality of first meta-lens ML1 is disposed on the display panel DPL. Each of the first meta-lens ML1 can be matched to each of pixel PXL as one-to-one correspondence. The first meta-lens ML1 can have same or slightly larger size than the pixel PXL.

The transparent layer LRL can be disposed on the first meta-lens ML1. The transparent layer LRL can have a predetermined uniform thickness. The transparent layer LRL can have a thickness corresponding to the focal length of the first meta-lens ML1.

On the upper surface of the transparent layer LRL, the pixel viewing area VPL can be defined as the image area for the pixel adjusted by the first meta-lens ML1. Since each pixel viewing area VPL can correspond to each pixel PXL, a plurality of the pixel viewing areas VPL are arrayed in a matrix manner on the upper surface of the transparent layer LRL. The arrangement type of the pixels PXL can be same with that of the pixel viewing area VPL. Each of the second meta-lens ML2 can be arranged as matching to each of the pixel viewing area VPL in one-to-one correspondence.

Unlike the conventional lens, the meta-lens can have different optical path from the optical path of the conventional lens. Therefore, the arrangement type of the pixel viewing area VPL can be different from that of the pixels PXL.

When the first meta-lens ML1 is set to condense the size of the pixel PXL small at a certain ratio, the pixel viewing area VPL can have a size smaller than that of the pixel PXL. The pixel viewing area VPL can have the same shape as that of the pixel PXL. On the other hand, since the meta-lens can freely adjust the light path unlike the conventional lens, the pixel viewing area VPL can have a shape completely different from the shape of the pixel PXL.

In the second aspect, each of the plurality of pixels PXL having a first surface size and arrayed in a matrix manner at the display area PA can be rearranged at the viewing area VA in a matrix manner, and can be projected to each of the plurality of the pixel viewing area VPL having a second surface size. Accordingly, the size of the pixel PXL can be optically reduced and the resolution is increased. As applying the flat panel display according to the second aspect of the present disclosure to a personal immersion display, the image information of the display panel can be provided in a viewing area corresponding to the user's eye focus without using conventional lens system. Since the conventional heavy and bulky convex and/or concave lenses are not used, the volume and weight can be remarkably reduced. In addition, a very simple structure can be provided by stacking ultra-thin meta-lens layers on the display panel without using any conventional lens system.

<Third Aspect>

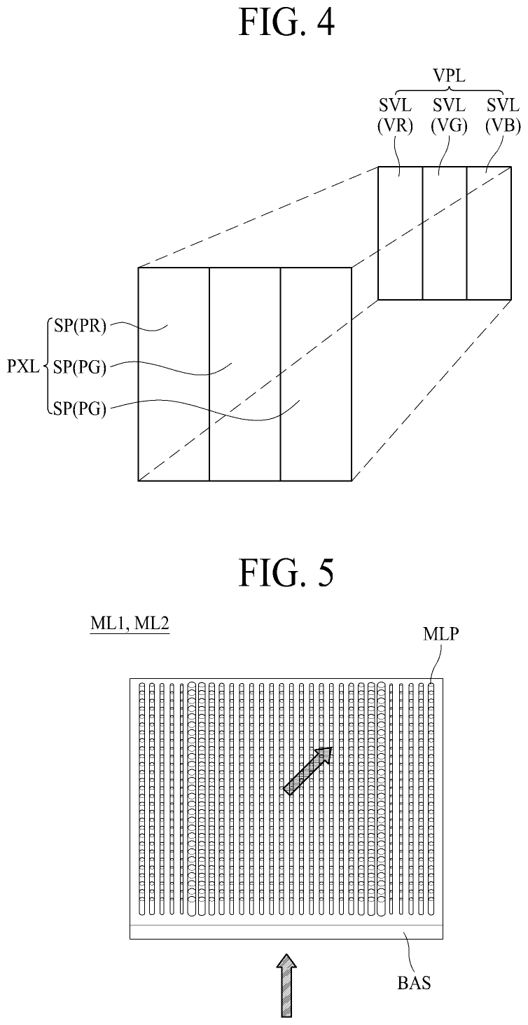

Hereinafter, referring to FIG. 4, the third aspect of the present disclosure will be described. FIG. 4 is a perspective view illustrating the structure of one pixel in a flat panel display according to a third aspect of the present disclosure. FIG. 4 can show one pixel PXL and one pixel viewing area VPL of FIG. 3. Therefore, in the following description, reference numerals not shown in FIG. 4 can be referred to FIG. 3.

FIG. 4 illustrates a case in which the pixel PXL of FIG. 3 can be configured with three sub-pixels SP. For example, one pixel PXL can include one red sub-pixel PR, one green sub-pixel PG and one blue sub-pixel PB. An image of one pixel PXL can be adjusted to the pixel viewing area VPL by the first meta-lens ML1. Therefore, one pixel viewing area VPL can include three sub viewing areas SVL. For example, one pixel viewing area VPL can include one red viewing area VR, one green viewing area VG and one blue viewing area VB.

The red sub-pixel PR of the pixel PXL can correspond to the red viewing area VR of the pixel viewing area VPL, the green sub-pixel PG can correspond to the green viewing area VG of the pixel viewing area VPL, and the blue sub-pixel PB can correspond to the blue viewing area VG of the pixel viewing area VPL.

Like the second aspect, each of the plurality of pixels PXL having a first surface size can be rearranged in a matrix manner at the viewing area VA, and can be projected to a plurality of the pixel viewing area VPL having a second surface size. Therefore, the size of the pixel PXL can be optically reduced, and the resolution can be increased. As applying the flat panel display according to the third aspect of the present disclosure to a personal immersion display, the image information of the display panel can be provided in a viewing area corresponding to the user's eye focus without using conventional lens system. Since the conventional heavy and bulky convex and/or concave lenses are not used, the volume and weight can be remarkably reduced. In addition, a very simple structure can be provided by stacking ultra-thin meta-lens layers on the display panel without using any conventional lens system.

Hereinafter, referring to FIG. 5, the meta-lens of the flat panel display according to the present disclosure will be explained. FIG. 5 is an enlarged view illustrating one example of meta-lens for a flat panel display according to the present disclosure.

The meta-lens can be implemented by arranging the meta materials regularly or irregularly on a base substrate BAS. Otherwise, the meta-lens can be implemented by irregularly arranging groups in which the meta materials are regularly arranged, or by regularly arranging groups in which the meta materials are irregularly arranged. Meta material refers to a state in which materials existing in nature or artificially made into nano-sized are aggregated at nano-intervals. The meta material can have different physical properties from the original material. In this disclosure, by making transparent materials in various nano sizes and arranging them regularly or irregularly on a transparent base substrate BAS, the light passing therethrough can be diffused, condensed and/or deflected.

For example, as shown in FIG. 5, the meta-lenses ML1 and ML2 can be formed by arranging columnar meta-materials MLP having a nano size made of a transparent material on a transparent base substrate BAS regularly or in a specific manner. In this case, when light incident in a vertical direction from the lower surface of the base substrate BAS can pass through the meta-lenses ML1 and ML2, the light can be refracted in a specific direction.

The arrangement method of the meta-material shown in FIG. 5 is one example, so it is not limited thereto. In addition, the arrangement method of the meta material in the first meta-lens ML1 can be different from the arrangement method of the metal material in the second meta-lens ML2. The arrangement method of the meta material in the plurality of meta-lenses ML1 described in the second aspect can be arranged in different arrangement method each other.

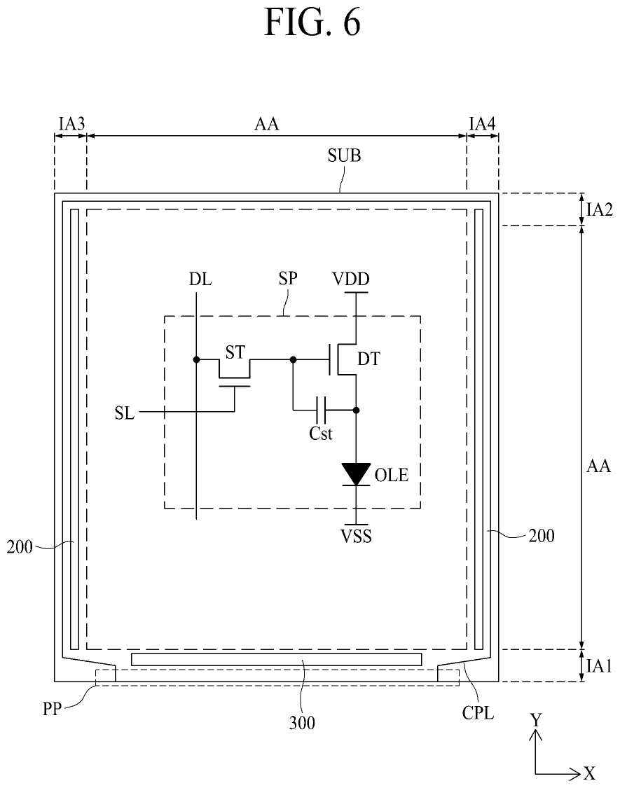

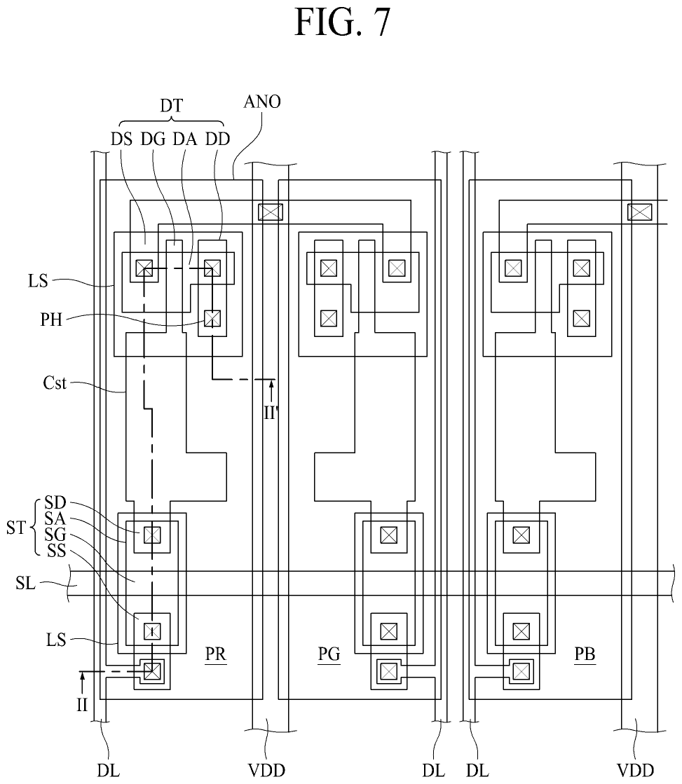

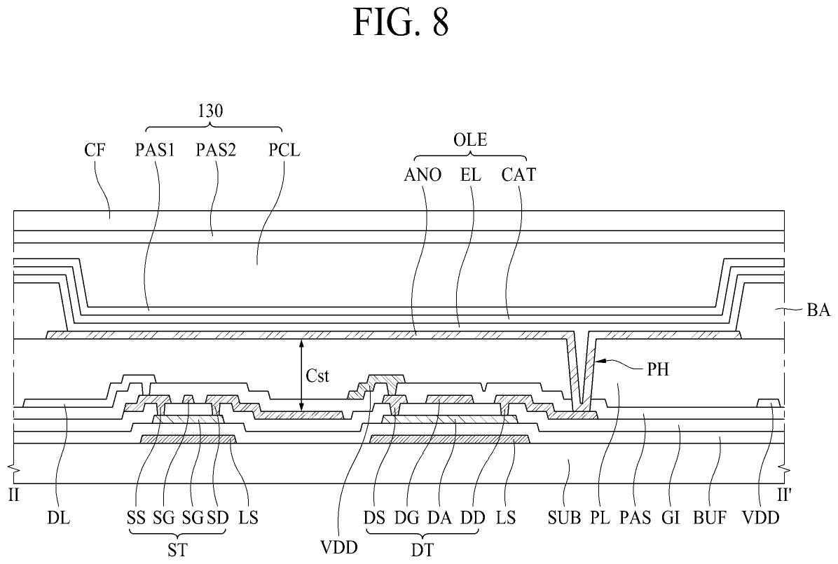

Hereinafter, referring to FIGS. 6 to 8, the display panel DPL according to the present disclosure will be described in detail. FIG. 6 is a plan view illustrating a structure of a display panel included in a flat panel display according to the present disclosure. FIG. 7 is an enlarged plan view illustrating a structure of a display panel included in a flat panel display according to the present disclosure. FIG. 8 is an enlarged cross-sectional view along cutting line II-IF in FIG. 7, for illustrating a structure of a display panel included in a flat panel display according to the present disclosure.

Referring to FIG. 6, the electroluminescence display according to the present disclosure comprises a substrate SUB, a sub-pixel SP, a common power line CPL and driving portions PP, 200 and 300. The substrate SUB, as a base substrate (or base layer), can be made of a glass, a metal or a silicon material, but it is not limited thereto. It is preferable to use an OLEDoS (OLED on Silicon) element that forms a pixel and driver on a silicon wafer for a personal immersion display. The substrate SUB is preferably transparent due to the characteristics of the display. However, in some cases, for example in the case of a top emission type, the substrate SUB can be made of an opaque material.

For example, the substrate SUB can two-dimensionally have a quadrangular shape, a quadrangular shape of which corners are rounded with a predetermined radius of curvature, or a non-quadrangular shape having at least six sides. Here, the substrate SUB having a non-quadrangular shape includes at least one protruding portion or at least one notched portion.

The substrate 110 can include a display area AA and a non-display area IA. The display area AA is provided in a substantially middle part of the substrate SUB and is defined as an area for displaying an image. For example, the display area AA has a quadrangular shape, a quadrangular shape of which corners are rounded with a predetermined radius of curvature, or a non-quadrangular shape having at least six sides. Here, the display area AA having a non-quadrangular shape includes at least one protruding portion or at least one notched portion.

The non-display area IA is provided in edges of the substrate SUB to surround the display area AA, and is defined as an area in which an image is not displayed or a circumferential area. For example, the non-display area IA includes a first non-display area IA1 that is provided at a first edge of the substrate, a second non-display area IA2 that is provided at a second edge of the substrate SUB which is parallel to the first non-display area IA1, a third non-display area IA3 that is provided at a third edge of the substrate SUB, and a fourth non-display area IA4 that is provided at a fourth edge of the substrate SUB which is parallel to the third non-display area IA3. For example, the first non-display area IA1 can be an upper (or lower) edge area of the substrate SUB, the second non-display area IA2 can be a lower (or upper) edge area of the substrate SUB, the third non-display area IA3 can be a left (or right) edge area of the substrate SUB, and the fourth non-display area IA4 can be a right (or left) edge area of the substrate SUB, but the present disclosure is not limited thereto.

A plurality of sub-pixels SP can be disposed in the display area AA of the substrate SUB. For example, a plurality of sub-pixels SP can be arranged in a matrix type in the display area AA of the substrate SUB. The sub-pixels SP can be defined by scan lines SL, data lines DL, and pixel driving power lines VDD.

The scan lines SL extend in a first direction X and are disposed at predetermined intervals in a second direction Y crossing the first direction X. The display area AA of the substrate SUB includes a plurality of scan lines SL that are parallel to each other in the first direction X and are separated from each other in the second direction Y. Here, the first direction X is defined as a horizontal direction of the substrate SUB and the second direction Y is defined as a vertical direction of the substrate SUB, but the present disclosure is not limited thereto and can be defined on the contrary thereto.

The data lines DL extend in the second direction Y and are disposed at predetermined intervals in the first direction X. The display area AA of the substrate SUB includes a plurality of data lines DL that are parallel to the second direction Y and are separated from each other in the first direction X.

The pixel driving power lines VDD are disposed on the substrate SUB to be parallel to the data lines DL. The display area AA of the substrate SUB includes a plurality of pixel driving power lines VDD that are parallel to the data lines DL. In some other examples, the pixel driving power lines VDD can be disposed to be parallel to the scan lines SL.

One unit pixel includes a red sub-pixel, a green sub-pixel, and a blue sub-pixel, and the unit pixel can further include a white sub-pixel. For example, the sub-pixel SP can be disposed in a stripe pattern in the display area AA. The stripe pattern refers to a structure in which sub-pixels of the same color are continuously arranged in one row or column, and sub-pixels of different colors are alternately arranged. For example, red sub-pixels form a first column, green sub-pixels form a second column, and blue sub-pixels form a third column. Then, a red column, a green column and a blue column can be repeatedly arranged.

For another example, the pixels can be disposed in a pentile structure in the display area AA. In this case, a unit pixel includes at least one red sub-pixel, at least two green sub-pixels, and at least one blue sub-pixel which are disposed in a two-dimensional polygonal shape. For example, in one unit pixel having a pentile structure, one red sub-pixel, two green sub-pixels, and one blue sub-pixel are two-dimensionally disposed in an octagonal shape. In this case, the blue sub-pixel has an opening area (or an emission area) which is the largest, and the green sub-pixel has an opening area which is the smallest.

The sub-pixel SP can include a pixel circuit ST and DT connected to a scan line SL, a data line and a pixel driving power line VDD which are surrounding the sub-pixel SP, and a light emitting element OLE connected to the pixel circuit.

The pixel circuit ST and DT can control a data current Ied supplied to the light emitting element OLE from the pixel driving power line VDD, based on the data voltage supplied from the data line DL.

For example, each pixel circuit includes at least two thin-film transistors ST and DT and one capacitor Cst. In detail, each pixel circuit can include a driving thin-film transistor DT that supplies a data current Ied based on a data voltage to the light emitting element OLE, a switching thin-film transistor ST that supplies the data voltage supplied from the data line DL to the driving thin-film transistor DT, and a capacitor Cst that stores a gate-source voltage of the driving thin-film transistor DT.

For example, the switching thin film transistor ST can perform a switching operation so that a data signal supplied from the data line DL is stored as a data voltage in the capacitor Cst in response to a scan signal supplied from the scan line SL. The driving thin film transistor DT can supply the driving current Ied between the pixel driving power line VDD and the low potential terminal Vss connected to the common power line CPL according to the data voltage stored in the capacitor Cst. The light emitting element OLE can emit light according to the driving current Ied formed by the driving thin film transistor DT.

The switching thin film transistor ST can include a source electrode SS connected to the data line DL, and a drain electrode SD connected to the gate electrode DG of the driving thin film transistor DT. The driving thin film transistor DT can include a source electrode DS connected to the pixel driving power line VDD, and a drain electrode DD connected to the anode electrode ANO of the light emitting element OLE. The capacitor Cst can include a first electrode connected to the gate electrode DG of the driving thin film transistor DT (or the drain electrode SD of the switching thin film transistor ST), and a second electrode connected to the anode electrode ANO of the light emitting element OLE

For another example, each pixel circuit can include at least three thin-film transistors and at least one capacitor. For example, the pixel circuit includes a current supply circuit, a data supply circuit, and a compensation circuit depending on operations (or functions) of the at least three thin-film transistors. Here, the current supply circuit includes a driving thin-film transistor that supplies a data current Ied based on a data voltage to the light emitting element OLE. The data supply circuit includes at last one switching thin-film transistors that supply the data voltage supplied form the data line DL to the current supply circuit in response to at least one scan signal. The compensation circuit includes at least one compensation thin-film transistor that compensates for change in characteristic values (a threshold voltage and/or mobility) of the driving thin-film transistor in response to at least one scan signal.

Each light emitting element OLE emits light with luminance corresponding to the data current Ied in response to the data current Ied which is supplied from the pixel circuit ST and DT. In this case, the data current Ied can flow from the pixel driving power line VDD to a common power line CPL via the driving thin film transistor DT and the light emitting element OLE.

The light emitting element OLE according one aspect can include an inorganic light emitting diode or an organic light emitting diode. For example, the light emitting element OLE can include a pixel driving electrode (or first electrode, or anode electrode) connected to the pixel circuit, an emission layer stacked on the pixel driving electrode, and a common electrode (or second electrode, or cathode electrode).

The common power line CPL is disposed in the non-display area IA of the substrate SUB and is electrically connected to the common electrode disposed in the display area AA. For example, the common power line CPL is disposed along the second to fourth non-display areas IA2, IA3, and IA4 which are adjacent to the display area AA of the substrate SUB with a constant line width, and surrounds parts of the display area AA other than the part adjacent to the first non-display area IA1 of the substrate SUB. One end of the common power line CPL is disposed on one side of the first non-display area IA1 and the other end of the common power line CPL is disposed on the other side of the first non-display area IA1. One end and the other end of the common power line CPL are disposed to surround the second to fourth non-display areas IA2, IA3, and IA4. Accordingly, the common power line CPL has two-dimensionally a “∩-shape” in which one side corresponding to the first non-display area IA1 of the substrate SUB is open.

The electroluminescence display according to the present disclosure can further comprise an encapsulation layer for protecting the light emitting element OLE. The encapsulation layer is formed on the substrate SUB to surround the display area AA and the top surface and the side surface of the common power line CPL. On the other hand, the encapsulation layer exposes one end and the other end of the common power line CPL in the first non-display area IA1. The encapsulation layer serves to prevent oxygen or moisture from permeating the light emitting elements OLE which are disposed in the display area AA. For example, the encapsulation layer can include at least one inorganic layer. For example, the encapsulation layer can include a plurality of inorganic layers and an organic layer interposed between the pluralities of inorganic layers.

A driving unit according to an embodiment of the present disclosure includes a pad portion PP, a gate driving circuit 200 and a driving integrated circuit 300.

The pad portion PP can include a plurality of pads which are provided in the non-display area IA of the substrate SUB. For example, the pad portion PP can include a plurality of common power pads, a plurality of data input pads, a plurality of driving power pads and a plurality of control signal input pads which are provided in the first non-display area IA1 of the substrate SUB.

The gate driving circuit 200 is provided in the third non-display area IA3 and/or the fourth non-display area IA4 of the substrate SUB and is connected to the scan lines SL provided in the display area AA in a one-to-one correspondence manner. The gate driving circuit 200 is formed as an integrated circuit in the third non-display area IA3 and/or the fourth non-display area IA4 of the substrate SUB in the same process as a process of manufacturing the pixels P, for example, a process of manufacturing the thin-film transistors. The gate driving circuit 200 drives a plurality of scan lines SL in a predetermined order by generating a scan signal on the basis of a gate control signal supplied from the driving integrated circuit 300 and outputting the generated scan signals in a predetermined order. For example, the gate driving circuit 200 can include a shift register.

The driving integrated circuit 300 is mounted in a chip mounting area which is defined in the first non-display area IA1 of the substrate SUB through a chip mounting (or bonding) process. Input terminals of the driving integrated circuit 300 are electrically connected to the pad portion PP and thus are electrically connected to a plurality of data lines DL provided in the display area AA and a plurality of pixel driving power lines VDD. The driving integrated circuit 300 receives various powers, a timing synchronization signal, and digital image data from a display driving circuit unit (or a host circuit) via the pad portion PP, generates gate control signals on the basis of the timing synchronization signal, controls driving of the gate driving circuit 200, converts the digital image data into analog pixel data voltages, and supplies the analog pixel data voltages to the corresponding data lines DL.

Referring to FIGS. 7 to 8, one sub-pixel of the electroluminescence display can include a scan line SL, a data line DL and a driving power line VDD. Further, one sub-pixel can include a switching thin film transistor ST, a driving thin film transistor DT, a light emitting diode OLE and a capacitor Cst. The driving power line VDD can be supplied with a high-potential voltage for driving the light emitting diode OLE.

For example, the switching thin film transistor ST can be disposed where the scan line SL and the data line DL are crossed. The switching thin film transistor ST includes a switching gate electrode SG, a switching source electrode SS and a switching drain electrode SD. The switching gate electrode SG is branched from the scan line SL, or is a part of the scan line SL as shown in FIG. 3. The switching source electrode SS is connected to the data line DL, and the switching drain electrode SD is connected to the driving thin film transistor DT. The switching thin film transistor ST selects a pixel to be driven by applying a data signal to the driving thin film transistor DT.

The driving thin film transistor DT drives the light emitting diode OLE disposed in a pixel (or sub-pixel) selected by the switching thin film transistor ST. The driving thin film transistor DT can include a driving gate electrode DG, a driving source electrode DS and a driving drain electrode DD. The driving gate electrode DG can be connected to the switching drain electrode SD of the switching thin film transistor ST. The driving source electrode DS is connected to the pixel driving power line VDD, and the driving drain electrode DD is connected to the anode electrode ANO of the light emitting diode OLE. The capacitor Cst can be formed between the switching drain electrode SD of the switching thin film transistor ST and the anode electrode ANO of the light emitting diode OLE.

The driving thin film transistor DT can be disposed between the pixel driving power line VDD and the light emitting diode OLE. The driving thin film transistor DT ma control the current flowing from the pixel driving power line VDD to the light emitting diode OLE according to the voltage of the gate electrode DG of the driving thin film transistor DT connected to the drain electrode SD of the switching thin film transistor ST.

FIG. 8 illustrates the structure of the thin film transistors ST and DT having the top-gate structure. The top-gate structure refers to a structure in which the semiconductor layers SA and DA can be firstly formed on the substrate SUB, and the gate electrodes SG and DG are formed on the gate insulating layer GI covering the semiconductor layers SA and DA. For another example, the thin film transistors ST and DT can have a bottom-gate structure. The bottom-gate structure refers to a structure in which the gate electrode is firstly formed on the substrate, and the semiconductor layer is formed on the gate insulating layer covering the gate electrode. The electroluminescence display according to the present disclosure preferably includes a thin film transistor having the top-gate structure in order to increase the aperture ratio, which is the ratio of the emission area to the pixel area, in implementing ultra-high density resolution.

In the case of the top-gate structure as shown in FIG. 8, the switching source electrode SS, the switching drain electrode SD, the driving source electrode DS and the driving drain electrode DD are formed on the level of the layer same with the gate electrodes SG and DG. For example, the source electrodes SS and DS and the drain electrodes SD and DD are formed at the same layer with the scan line SL and the gate electrodes SG and DG, but the data line DL and the pixel driving power line VDD are formed on the layer different from the scan line SL. The intermediate insulating layer ILD is deposited on the gate electrodes SG and DG, the source electrodes SS and DS and the drain electrodes SD and DD. The data line DL and the pixel driving power line VDD are formed on the intermediate insulating layer ILD.

The light emitting diode OLE includes an anode electrode ANO, an emission layer EL and a cathode electrode CAT. The light emitting diode OLE can emit lights according to the current adjusted by the driving thin film transistor DT, accordingly, the luminance of the electroluminescence display can be controlled. The anode electrode ANO of the light emitting diode OLE is connected to the driving drain electrode DD of the driving thin film transistor DT, and the cathode electrode CAT is connected to the low power line VSS supplied with the low-level potential voltage. The light emitting diode OLE can be driven by the low level potential voltage constantly supplied from the low power line VSS and the high level potential voltage frequently adjusted by the driving thin film transistor DT.

A passivation layer PAS is deposited on the surface of the substrate SUB. The passivation layer PAS can be made of an inorganic material such as the silicon oxide or a silicon nitride. A planarization layer PL is deposited on the passivation layer PAS. The planarization layer PL can be a layer for flattening the non-uniform (or uneven) surface of the substrate SUB on which the thin film transistors ST and DT are formed. In order to make the height difference uniform, the planarization layer PL can be formed of an organic material. The pixel contact hole PH can be formed at the passivation layer PAS and the planarization layer PL for exposing a portion of the driving drain electrode DD of the driving thin film transistor DT.

The anode electrode ANO is formed on the top surface of the planarization layer PL. The anode electrode ANO can contact to the driving drain electrode DD of the driving thin film transistor DT via the pixel contact hole PH. The anode electrode ANO can have different configuration according to the light emitting type of the light emitting diode OLE. In the case of the bottom emission type that provides light in the direction of the substrate SUB, the anode electrode ANO can be formed of a transparent conductive material. In the case of the top emission type that provides light in the opposite direction of the substrate SUB, the anode electrode ANO can be formed of a metal material having excellent light reflectance. For example, the anode electrode ANO can be made of any one of aluminum (Al), silver (Ag), molybdenum (Mo), gold (Au), magnesium (Mg), calcium (Ca) or barium (Ba) or alloys of any two or more of them.

The electroluminescence display according to the present disclosure can have the top-emission type suitable for implementing the ultra-high-resolution. For the top-emission type, it is preferable that the anode electrode ANO has a maximum area in the pixel area defined by the data line DL, the pixel driving power line VDD and the scan line SL. In this case, the thin film transistors ST and DT can be disposed under the anode electrode ANO, as overlapping with the anode electrode ANO. Further, some of the data line DL, the pixel driving power line VDD and the scan line SL can be overlapped with the anode electrode ANO.

A bank BA is formed on the anode electrode ANO. The bank BA can cover the circumference areas of the anode electrode ANO, and expose most of middle portions of the anode electrode ANO. The exposed area of the anode electrode ANO by the bank BA can be defined as an emission area of the pixel.

The emission layer EL is deposited on the anode electrode ANO. The emission layer EL can be formed on the entire display area AA of the substrate SUB to cover the anode electrode ANO and the bank BA. The emission layer EL according to one aspect can include two or more emission portions which are vertically stacked for providing white light. For example, the emission layer EL can include a first emission layer and a second emission layer on the first emission layer for providing white light by mixing a first light from the first emission layer with a second light from the second emission layer.

For another embodiment, the emission layer EL can include any one of blue emission layer, green emission layer and red emission layer for providing color light allocated at the pixel. In this case, the emission layer EL can be disposed as being isolated within each emission area defined by the bank BA. In addition, the light emitting diode OLE can further include functional layers for enhancing the emission efficiency and/or the light time of the emission layer EL.

A cathode electrode CAT is deposited on the emission layer EL as being in surface-contact with the emission layer EL. The cathode electrode CAT is deposited as covering whole surface of the substrate SUB as being in connected with the emission layer EL disposed at all pixels. For the top emission type, the cathode electrode CAT preferably includes a transparent conductive material such as indium-tin-oxide (ITO) or indium-zinc-oxide (IZO).

An encapsulation layer 130 is deposited on cathode electrode CAT of the light emitting diode OLE. The encapsulation layer 130 can be formed to surround all of the top surface and the side surface of the light emitting diode OLE. The encapsulation layer 130 serves to prevent oxygen or moisture from permeating the light emitting diode OLE.

For example, the encapsulation layer 130 includes a first inorganic encapsulation layer PAS1, an organic encapsulation layer PCL on the first inorganic encapsulation layer PAS1, and a second inorganic encapsulation layer PAS2 on the organic encapsulation layer PCL. The first inorganic encapsulation layer PAS1 and the second inorganic encapsulation layer PAS2 serve to prevent permeation of moisture or oxygen. For example, the first inorganic encapsulation layer PAS1 and the second inorganic encapsulation layer PAS2 can be formed of an inorganic material such as silicon nitride, aluminum nitride, zirconium nitride, titanium nitride, hafnium nitride tantalum nitride, silicon oxide, aluminum oxide, or titanium oxide. The first inorganic encapsulation layer PAS1 and the second inorganic encapsulation layer PAS2 can be formed through a chemical vapor deposition (CVD) process or an atomic layer deposition (ALD) process.

The organic encapsulation layer PCL has a structure in which it is sealed (surrounded) by the first inorganic encapsulation layer PAS1 and the second inorganic encapsulation layer PAS2. The organic encapsulation layer PCL is formed in a thickness greater than that of the first inorganic encapsulation layer PAS1 and/or the second inorganic encapsulation layer PAS2 such that particles which can be generated in the manufacturing process can be adsorbed and/or blocked. The organic encapsulation layer PCL can be formed of an organic material such as silicon oxycarbon (SiOCz) acryl or an epoxy-based resin. The organic encapsulation layer PCL can be formed using a coating process, for example, an ink-jet coating process or a slit coating process.

The electroluminescence display according to the present disclosure can further include a light shield layer LS. The light shield layer LS can be disposed under the semiconductor layers SA and DA for preventing the characteristics of the channel from being changed by light intruded into the semiconductor layers SA and DA. For example, a light shield layer LS is firstly formed where the semiconductor layers SA and DA are formed on the substrate SUB, and then a buffer layer BUF can be deposited on the entire surface of the substrate SUB.

In addition to preventing external light from penetrating into the semiconductor layers SA and DA, the light shield layer LS can be used as a repair element to connect a defective pixel to a neighboring normal pixel to operate normally. Otherwise, the light shield layer LS can be used for the data line DL or the pixel driving power line VDD. As another example, since the light shield layer LS overlaps the semiconductor layers SA and DA, it can be used as a gate electrode for implementing a thin film transistor having a double gate structure.

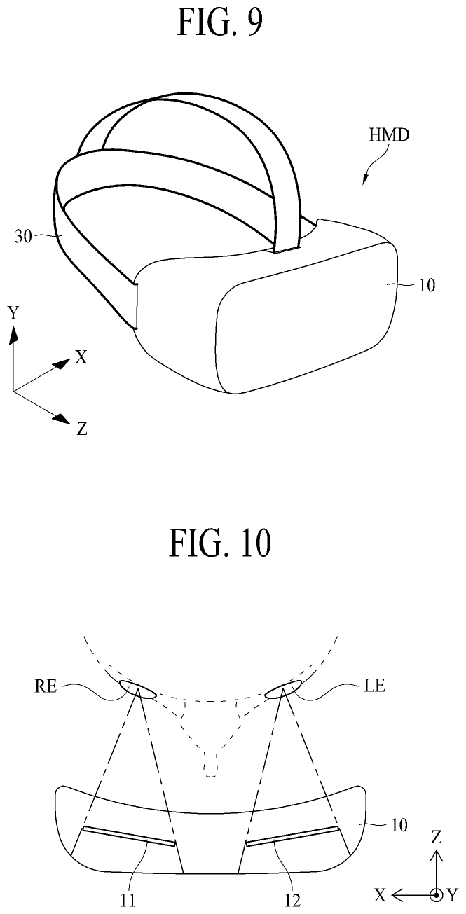

Hereinafter, referring to FIGS. 9 and 10, a personal immersion display having the flat panel display according to the present disclosure will be described. FIG. 9 is a diagram illustrating a personal immersion display according an aspect of the present disclosure. FIG. 10 is a diagram illustrating a state of wearing a personal immersion display according to an aspect of the present disclosure.

Referring to FIGS. 9 and 10, a head mount display HMD according to one aspect of the present disclosure can comprise a housing case 10, a right flat panel display 11, a left flat panel display 12 and a head mounting band 30.

The housing case 10 accommodates the right flat panel display 11 and the left flat panel display 12 which provide images of these flat panel displays to the right eye RE and the left eye LE of user, respectively. Each flat panel display can include the meta-lens layer and the display panel according to various aspects of the present disclosure. In particular, the display panel can be the electroluminescence display panel. The flat panel display according to the aspects of the present disclosure has been described in detail above with reference to FIGS. 1 to 8.

The housing case 10 can be formed to provide the same image to the right eye RE and the left eye LE. Alternatively, the housing case 10 can be formed so that the right eye image is displayed on the right RE and the left eye image is displayed on the left eye EL to implement a stereoscopic display having binocular parallax.

In the housing case 10, the right flat panel display 11 can be disposed in front of the right eye RE and the left flat panel display 12 can be disposed in front of the left eye LE, as shown in FIG. 10. FIG. 10 illustrates a cross-sectional view of the housing case 10 as viewing from above. The right flat panel display 11 can provide the right eye image, and the left flat panel display 12 can provide the left eye image. Accordingly, the right eye image displayed on the right flat panel display 11 can be provided on the user's right eye only, and the left eye image displayed on the left flat panel display 12 can be provided on the user's left eye only.

The head mounting band 30 can be fixed to the housing case 10. The head mounting band 30 is illustrated to be formed to surround the upper surface and both sides of the user's head, but it is not limited thereto. The head mounting band 30 can be for settling the head mounted display to the user's head, and can be formed in the shape of an eyeglass frame or a helmet.

The personal immersion display according to the present disclosure does not require a conventional lens for providing an image to the user's right and left eyes, by using a flat panel display with a meta-lens. Accordingly, without a conventional lens that is bulky and heavy, the personal immersion display according to the present disclosure has a very simple structure and can be manufactured very thinly and very lightly. In addition, unlike the conventional lens, the meta-lens has a feature that can be manufactured so as not to be subject to the optical limitations of the conventional lens according to the arrangement structure of the meta material. For example, the meta-lens can be formed to overcome spherical aberration, curved aberration or polarization phenomenon.

In the previous descriptions, they are focused on the case in which the size of the pixel area PA disposed on the display panel DPL is reduced to form an image of the pixel PXL which has become smaller in the viewing area VA. These are explained as the cases in which the meta-lens simply has a function of conversing light. However, the present disclosure is not limited to the purpose of simply converting or diverting light by the meta-lens. The meta-lens can have some features of arbitrarily setting the path of light or the degree of refraction of light. Accordingly, the image of the pixel PXL can be formed in more various ways than those described above.

As an example, in the above descriptions, it is focused on the case where the viewing area VA completely overlaps the display area PA and their centers coincide with each other. However, the viewing area VA can be controlled to be focused so as to be biased toward either side within the range of the display area VA. As another example, the viewing area VA can be set to overlap a part of the range of the display area PA, and the remaining area to be outside the display area PA. As still another example, the viewing area VA can be set to be formed at a position where there is no overlapping portion with the display area PA. By applying these various functions, more various structure can be implemented in the personal immersion display.

For example, in the case of an augmented reality display in the form of glasses, according to the related technology, an image of the display is projected onto one side of the spectacle lens through a very complex structure using a plurality of prisms and/or reflectors. However, according to the present disclosure, a position at which an image is projected can be arbitrarily set by only the combination of a flat panel display with a meta-lens.

The features, structures, effects and so on described in the above examples of the present disclosure are included in at least one example of the present disclosure, and are not limited to only one example. Furthermore, the features, structures, effects and the likes explained in at least one example can be implemented in a combination or modification manner with respect to other examples by those skilled in the art to which this disclosure belongs. Accordingly, the contents related to such combinations and modifications should be construed as being included in the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents. These and other changes can be made to the aspects in light of the above-detailed description. In general, in the following claims, the terms used should not be construed to limit the claims to the specific aspects disclosed in the specification and the claims, but should be construed to include all possible aspects along with the full scope of equivalents to which such claims are entitled. Accordingly, the claims are not limited by the present disclosure.

What is claimed is:

1. A flat panel display comprising:
a display panel including a display area having a first surface area;
a first meta-lens disposed on the display panel to correspond to the display area;
a transparent layer disposed on the first meta-lens and having a first thickness;
a viewing area having a second surface area smaller than the first surface area, the viewing area defined on an upper surface of the transparent layer; and
a second meta-lens disposed on the upper surface of the transparent layer to correspond to the viewing area.

2. The flat panel display according to claim 1, wherein the first meta-lens converts incident light from the display area to emit output light directed to the viewing area, and
wherein the second meta-lens converts the output light provided in the viewing area into parallel light, and emits the parallel light directed to outside.

3. The flat panel display according to claim 2, wherein the output light is formed by focusing and deflecting the incident light corresponding to the first surface area to the second surface area, and
wherein the parallel light is formed by maintaining the output light corresponding to the second surface area in parallel with same area.

4. The flat panel display according to claim 1, wherein the display panel includes a plurality of pixels arrayed in the display area with a N×M matrix manner, where N and M are natural numbers, and
wherein a plurality of pixel viewing areas are arrayed in the viewing area with the N×M matrix manner corresponding to the pixels.

5. The flat panel display according to claim 4, wherein each pixel has a pixel size,
wherein the first meta-lens include a plurality of first unit meta-lenses allocated to each pixel,
wherein each pixel viewing area has a pixel viewing size smaller than the pixel size, and
wherein the second meta-lens includes a plurality of second unit meta-lenses allocated to each pixel viewing area.

6. The flat panel display according to claim 5, wherein each of the first unit meta-lenses corresponds one-to-one with each of the second unit meta-lenses, respectively,
wherein the first unit meta-lens provides incident light from the pixel corresponding to the first unit meta-lens to the pixel viewing area allocated to the second unit meta-lens corresponding to the first unit meta-lens, and
wherein the second meta-lens converts the incident light to emit as the parallel light.

7. The flat panel display according to claim 4, wherein each of the pixels includes at least three sub-pixels, and
wherein each pixel viewing area includes at least three sub viewing areas corresponding to the at least three sub-pixels.

8. The flat panel display according to claim 7, wherein each of the sub-pixels has a sub pixel size,
wherein the first unit meta-lens includes a first sub meta-lens allocated to each sub-pixel,
wherein each sub viewing area includes a sub viewing size smaller than the sub pixel size, and
wherein the second unit meta-lens includes a second sub meta-lens allocated to each sub viewing area.

9. The flat panel display according to claim 8, wherein the first sub meta-lenses correspond to one-to-one with the second sub meta-lenses,
wherein the first sub meta-lens provides incident light from the sub-pixel corresponding to the first sub meta-lens to the sub viewing area allocated to the second sub meta-lens corresponding to the first sub meta-lens, and
wherein the second sub meta-lens converts the incident light to emit as the parallel light.

10. The flat panel display according to claim 1, wherein the transparent layer has a refractive index smaller than the first meta-lens and the second meta-lens.

11. The flat panel display according to claim 1, wherein the display panel includes:
a driving element layer disposed on a substrate;
a planarization layer covering the driving element layer;
a light emitting element layer disposed on the planarization layer; and
a color filter layer disposed on the light emitting element layer.

12. The flat panel display according to claim 11, wherein the light emitting element layer includes:
a first electrode disposed in each of the plurality of pixels arrayed in the N×M matrix manner on the planarization layer;
an emission layer on the first electrode; and
a second electrode on the emission layer as covering the plurality of pixels.

13. The flat panel display according to claim 12, wherein the color filter layer includes a plurality of color filters allocated to the plurality of pixels.

14. The flat panel display according to claim 1, wherein the first meta-lens has an area greater than the display area, and wherein the second meta-lens has an area greater than the viewing area.
